(19) United States
(12) Patent Application Publication
(10) Pub. No.: US 2026/0058634 A1
(43) Pub. Date: Feb. 26, 2026

(54) BULK ACOUSTIC WAVE DEVICE WITH ENGINEERED REGION

(71) Applicant: Skyworks Global Pte. Ltd., Singapore (SG)

(72) Inventors: Kwang Jae Shin, Yongin-si (KR); Zongliang Cao, Irvine, CA (US); Yanbo He, Irvine, CA (US); Stefan Bader, Fort Collins, CO (US)

(21) Appl. No.: 19/279,944

(22) Filed: Jul. 24, 2025

Related U.S. Application Data
(60) Provisional application No. 63/676,244, filed on Jul. 26, 2024.
(60) Provisional application No. 63/676,193, filed on Jul. 26, 2024.

(51) Int. Cl. H03H 9/17; H03H 9/02; H03H 9/56

(52) U.S. Cl. CPC H03H 9/173; H03H 9/02015; H03H 9/02102; H03H 9/568

(57) ABSTRACT

Aspects of this disclosure relate to bulk acoustic wave devices that include a first electrode, a second electrode, and a piezoelectric layer that includes a first region and a second region. The first region laterally surrounds the second region. The first region has a first effective piezoelectric coefficient having a greater magnitude than a second effective piezoelectric coefficient of the second region. Related acoustic wave filters, multiplexers, radio frequency modules, radio frequency systems, wireless communication devices, methods of manufacture, and methods of filtering are disclosed.

### CROSS REFERENCE TO PRIORITY APPLICATIONS

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/676,193, filed Jul. 26, 2024 and titled “BULK ACOUSTIC WAVE DEVICE WITH ENGINEERED REGION,” and claims the benefit of priority of U.S. Provisional Application No. 63/676,244, filed Jul. 26, 2024 and titled “BULK ACOUSTIC WAVE DEVICE WITH THERMALLY CONDUCTIVE STRUCTURE FOR HEAT DISSIPATION,” the disclosures of each of which are hereby incorporated by reference in their entireties and for all purposes.

### BACKGROUND

### Technical Field

The disclosed technology relates to acoustic wave devices. Embodiments of this disclosure relate to bulk acoustic wave resonators with an engineered region.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

For BAW devices, achieving a high quality factor (Q) is generally desirable. Suppressing and/or attenuating spurious mode(s) and dissipating heat in BAW devices is also generally desirable. There are technical challenges related to increasing Q, further suppressing spurious mode(s), and improving heat dissipation while meeting other performance specifications for BAW devices.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a bulk acoustic wave device that includes an acoustic reflector, a first electrode, a second electrode, and a piezoelectric layer positioned vertically between the first electrode and the second electrode. The piezoelectric layer includes a first region having a first effective piezoelectric coefficient and a second region having a second effective piezoelectric coefficient. The first effective piezoelectric coefficient has a greater magnitude than the second effective piezoelectric coefficient. The first region vertically overlaps with the acoustic reflector. The first region laterally surrounds the second region.

The second region can be located at a center of the first region.

The piezoelectric layer can include one or more additional regions each having a respective effective piezoelectric coefficient with a lower magnitude than the first effective piezoelectric coefficient. The first region can laterally surround each of the one or more additional regions.

Portions of the first and second electrodes and the second region of the piezoelectric layer can form a metal-insulator-metal capacitor.

The piezoelectric layer can include a third region laterally surrounding the first region. The first effective piezoelectric coefficient can have a greater magnitude than a third effective piezoelectric coefficient of the third region. The bulk acoustic wave device can include a frame structure vertically overlapping the third region. The bulk acoustic wave device can include a thermally conductive structure in thermal communication with the second region of the piezoelectric layer. The thermally conductive structure can provide a heat dissipation path away from the piezoelectric layer.

The bulk acoustic wave device can include a thermally conductive structure in thermal communication with the second region of the piezoelectric layer, in which the thermally conductive structure extends through the acoustic reflector. The bulk acoustic wave device can include a thermally conductive pillar at least partly vertically overlapping with the second region of the piezoelectric layer. The thermally conductive pillar can be in physical contact with the first electrode. The bulk acoustic wave device can include a conductor embedded in a dielectric layer connected to the thermally conductive pillar. The bulk acoustic wave device can include a support substrate and a conductive through substrate via extending through the support substrate, in which the piezoelectric layer is positioned over the support substrate, and in which the conductive through substrate via is connected to the conductor embedded in the dielectric layer.

The acoustic reflector can be an air cavity.

Another aspect of this disclosure is a bulk acoustic wave device that includes an acoustic reflector, a first electrode, a second electrode, and a piezoelectric layer positioned vertically between the first electrode and the second electrode. The piezoelectric layer has a first region and a second region. The second region is laterally surrounded by the first region over the acoustic reflector. The first region is in electrical communication with the first and second electrodes. The second region is engineered such that portions of the first and second electrodes and the second region define a metal-insulator-metal capacitor.

The piezoelectric layer can include a third region laterally surrounding the first region. An effective piezoelectric coefficient of the first region can have a greater magnitude than an effective piezoelectric coefficient of the third region. The bulk acoustic wave device can include a frame structure vertically overlapping the third region.

Another aspect of this disclosure is a bulk acoustic wave device having a middle region, a peripheral region, and an acoustically active region between the middle region and the peripheral region. The bulk acoustic wave device includes a first electrode, a second electrode, and a piezoelectric layer positioned between the first electrode and the second electrode. The piezoelectric layer has an effective piezoelectric coefficient in the acoustically active region with a higher magnitude than in the middle region and the peripheral region.

The middle region can be located at a center of the acoustically active region.

The bulk acoustic wave device can include a raised frame structure in the peripheral region.

The bulk acoustic wave device can include a thermally conductive pillar in the middle region. The bulk acoustic wave device can include a conductor embedded in a dielectric layer connected to the thermally conductive pillar. The bulk acoustic wave device can include a support substrate and a conductive through substrate via extending through the support substrate. The piezoelectric layer can be positioned over the support substrate. The conductive through substrate via can be connected to the conductor embedded in the dielectric layer.

Another aspect of this disclosure is a bulk acoustic wave device that includes a first electrode, a second electrode, a piezoelectric layer positioned vertically between the first electrode and the second electrode, and a thermally conductive structure configured to provide a heat dissipation path from the second region away from the piezoelectric layer. The piezoelectric layer includes a first region having a first effective piezoelectric coefficient and a second region having a second effective piezoelectric coefficient. The first effective piezoelectric coefficient has a greater magnitude than the second effective piezoelectric coefficient. The first region is positioned over an acoustic reflector. The second region is positioned laterally between portions of the first region.

The second region can be located at a center of the first region.

The bulk acoustic wave device can include a support substrate and a cavity between at least a portion of the support substrate and the first electrode. The thermally conductive structure can include a pillar extending at least partially between the first electrode and the support substrate. The pillar can have a diameter in a range between 0.5 micrometers and 30 micrometers. The pillar can have a diameter in a range between 3 micrometers and 10 micrometers. The thermally conductive structure can include a conductor embedded in dielectric material, where the conductor is connected to the pillar. The thermally conductive structure can include a conductive via extending through the support substrate, where the conductive via connected to the conductor.

The thermally conductive structure can be in contact with a portion of the first electrode. The portion of the first electrode can be positioned vertically between the thermally conductive structure and the second region of the piezoelectric layer.

The thermally conductive structure can include a dielectric material. The thermally conductive structure can be metallic. The thermally conductive structure can include at least one of molybdenum, copper, chromium, a metal alloy, aluminum nitride, beryllium oxide, silicon carbide, silicon nitride, or diamond.

The thermally conductive structure can be symmetric about an axis that extends through the second region.

The piezoelectric layer can include one or more additional regions each having a respective effective piezoelectric coefficient with a lower magnitude than the first effective piezoelectric coefficient. The first region can laterally surround each of the one or more additional regions.

Another aspect of this disclosure is a bulk acoustic wave structure that includes a bulk acoustic wave device in accordance with any suitable principles and advantages disclosed herein and a second bulk acoustic wave device. The second bulk acoustic wave device can include a third region of the piezoelectric layer having a third effective piezoelectric coefficient and a fourth region having a fourth effective piezoelectric coefficient. The third effective piezoelectric coefficient can have a greater magnitude than the fourth effective piezoelectric coefficient.

The thermally conductive structure can provide a heat dissipation path from the fourth region away from the piezoelectric layer. The bulk acoustic wave structure can include a support substrate. The support substrate can include a conductive through substrate via connected to the thermally conductive structure.

Another aspect of this disclosure is a bulk acoustic wave device having a middle region, a peripheral region, and a main acoustically active region between the middle region and the peripheral region. The bulk acoustic wave device includes a first electrode, a second electrode, a piezoelectric layer positioned between the first electrode and the second electrode, and a thermally conductive structure in the middle region. The piezoelectric layer has an effective piezoelectric coefficient with a higher magnitude in the main acoustically active region than in both the middle region and the peripheral region.

The thermally conductive structure can include a pillar extending at least partially between the first electrode and a support substrate. The pillar can have a diameter in a range between 0.5 micrometers and 30 micrometers. The thermally conductive structure can include a conductor embedded in dielectric material, and the conductor is connected to the pillar.

Another aspect of this disclosure is an acoustic wave filter for filtering a radio frequency signal. The acoustic wave filter includes a bulk acoustic wave device in accordance with any suitable principles and advantages disclosed herein and a plurality of additional acoustic wave resonators. The bulk acoustic wave device and the plurality of additional acoustic wave resonators are configured to filter the radio frequency signal.

Another aspect of this disclosure is a multiplexer for filtering radio frequency signals. The multiplexer includes a first filter including a bulk acoustic wave device in accordance with any suitable principles and advantages disclosed herein, and a second filter coupled to the first filter at a common node.

Another aspect of this disclosure is a radio frequency module that includes a filter including a bulk acoustic wave device in accordance with any suitable principles and advantages disclosed herein, radio frequency circuitry, and a package structure enclosing the filter and the radio frequency circuitry.

Another aspect of this disclosure is a radio frequency system that includes an antenna, a filter including a bulk acoustic wave device in accordance with any suitable principles and advantages disclosed herein, and an antenna switch configured to selectively electrically connect the antenna and a signal path that includes the filter.

Another aspect of this disclosure is a wireless communication device that includes a radio frequency front end including a filter that includes a bulk acoustic wave device in accordance with any suitable principles and advantages disclosed herein, an antenna coupled to the radio frequency front end, a transceiver in communication with the radio frequency front end, and a baseband system in communication with the transceiver.

Another aspect of this disclosure is a method of radio frequency signal processing. The method includes receiving a radio frequency signal via at least an antenna; and filtering the radio frequency signal with a filter that includes a bulk acoustic wave device in accordance with any suitable principles and advantages disclosed herein.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a bulk acoustic wave (BAW) device according to an embodiment.

FIG. 1B is a top plan view of a portion of the BAW device of FIG. 1A.

FIG. 2A is a schematic cross-sectional side view of a BAW device according to an embodiment.

FIG. 2B is an example schematic top plan view of the BAW device of FIG. 2A.

FIG. 2C is another example schematic top plan view of the BAW device of FIG. 2A.

FIG. 3A is a schematic cross-sectional side view of a BAW device according to an embodiment.

FIG. 3B is a schematic top plan view of the BAW device of FIG. 3A.

FIG. 4 is a schematic cross-sectional side view of a BAW structure according to an embodiment.

FIG. 5A is a schematic cross-sectional side view of a BAW device according to an embodiment.

FIG. 5B is an example of a BAW solidly mounted resonator (SMR) according to an embodiment.

FIGS. 6A, 6B, and 6C are schematic top plan views of BAW devices according to embodiments.

FIG. 7A is a schematic diagram of a ladder filter that includes one or more BAW resonators according to an embodiment.

FIG. 7B is schematic diagram of a band pass filter.

FIGS. 8A, 8B, 8C, and 8D are schematic diagrams of multiplexers that include a filter with one or more BAW resonators according to an embodiment.

FIGS. 9, 10, and 11 are schematic block diagrams of modules that include a filter with one or more BAW resonators according to an embodiment.

FIG. 12 is a schematic block diagram of a wireless communication device that includes a filter with one or more BAW resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other.

Acoustic wave filters can filter radio frequency (RF) signals in a variety of applications, such as in an RF front end of a mobile phone. An acoustic wave filter can include bulk acoustic wave (BAW) devices. A film acoustic wave resonator (FBAR) and a BAW solidly mounted resonator (SMR) are examples of BAW devices. BAW devices can generate heat during operation. Increasing the quality factor (Q) of a given bulk acoustic wave (BAW) resonator can effectively reduce energy losses. Such energy losses can include, for example, insertion losses within a filter or phase noise in an oscillator. BAW resonator performance can be enhanced and/or optimized by one or more of area, geometry, frame structure, or the like. BAW devices can include frame structures, such as raised frame structures and/or recessed frame structures.

BAW devices can include frame structures. A frame structure is a structure that adjusts mass loading in a portion of a BAW device over an acoustic reflector. A frame structure can include a raised frame structure that adds mass loading and/or a recessed frame structure that reduces mass loading. A raised frame structure can include an additional layer and/or a thicker portion of material that increases mass loading in a portion of a BAW device relative to a main acoustically active region. In some applications, a raised frame layer can include a different material than layers in contact with the raised frame layer. In some applications, a raised frame layer can include a same material as a layer in contact with the raised frame layer. A raised frame structure can be a multi-layer structure that includes two or more raised frame layers. A recessed frame structure can include a thinner portion of a layer of a BAW device that decreases mass loading in a portion of the BAW device relative to a main acoustically active region. Certain BAW devices include a frame structure around the main acoustically active region of the BAW device. Such a frame structure can be included around a periphery of the BAW device. In certain applications, the frame structure can surround the main acoustically active region in plan view. In some other applications, the frame structure can be around some but not all of the main acoustically active region in plan view.

A BAW device can include a first electrode, a second electrode, and a piezoelectric layer positioned between the first and second electrodes. A frame structure, such as a raised frame and/or a recessed frame, can be positioned around a main acoustically active region of the BAW device to reduce lateral energy leakage from the main acoustically active region. A region of the BAW device that includes the frame structure can be referred to as a frame region. A raised frame structure can create a resonance at a frequency that is below a resonant frequency of the main acoustically active region of the BAW device. This resonance associated with the raised frame structure can be below a main resonant frequency of the BAW device. A resonance associated with the raised frame structure can be referred to as a frame mode, and more specifically a raised frame mode. The raised frame mode can be undesirable in certain applications. At least a portion of the piezoelectric layer in the frame region can be engineered to suppress the frame mode.

Overheating can degrade the performance of BAW devices and/or damage the BAW devices. Therefore, heat durability and/or sufficient heat dissipation can be significant for BAW devices. This disclosure provides technical solutions related to heat durability and/or heat dissipation in BAW devices. A piezoelectric layer can be engineered to have less acoustic activity in a region surrounded by a main acoustically active region. This can reduce heat in such an engineered region. In certain applications, a thermally conductive pillar can provide a heat dissipation path for heat to flow from the engineered region away from the piezoelectric layer. The thermally conductive pillar can be connected to a buried conductor and/or a through substrate via in certain applications.

A BAW device can include a support substrate; a resonator including a first electrode, a second electrode, a piezoelectric layer between the first and second electrodes; and an acoustic reflector, such as air cavity, between the support substrate and the resonator. Heat is generated by the resonator during operation, and the heat can flow laterally through the piezoelectric layer. The piezoelectric layer can provide a heat dissipation path to a more thermally conductive element than the acoustic reflector to dissipate heat. For example, the piezoelectric layer can provide a heat dissipation path to the support substrate. However, a temperature at or near a center of the resonator can be significantly higher due to its heat dissipation path length. Therefore, an electrode of the resonator can be overheated at or near the center of the resonator. In some applications, a region that generates the most heat may not be the center of the resonator. In such applications, the region of the resonator that generates the most heat may be overheated.

Embodiments of this disclosure relate to BAW devices (e.g., BAW resonators) that include an engineered region and a regular region of a piezoelectric layer. The engineered region can be a region of the piezoelectric layer and be laterally surrounded by the regular region of the piezoelectric layer. The regular region can surround the engineered region over an acoustic reflector (e.g., an air cavity). The engineered region of the piezoelectric layer can have significantly less piezoelectric activity than the regular region, which can mitigate overheating in the BAW device and thereby improve heat durability. In some embodiments, a thermally conductive heat path can be included to further improve the heat durability. For example, a thermally conductive pillar can be provided for improved cooling. The thermally conductive pillar can be thermally connected to the engineered region of the piezoelectric layer to transfer heat away from the piezoelectric layer.

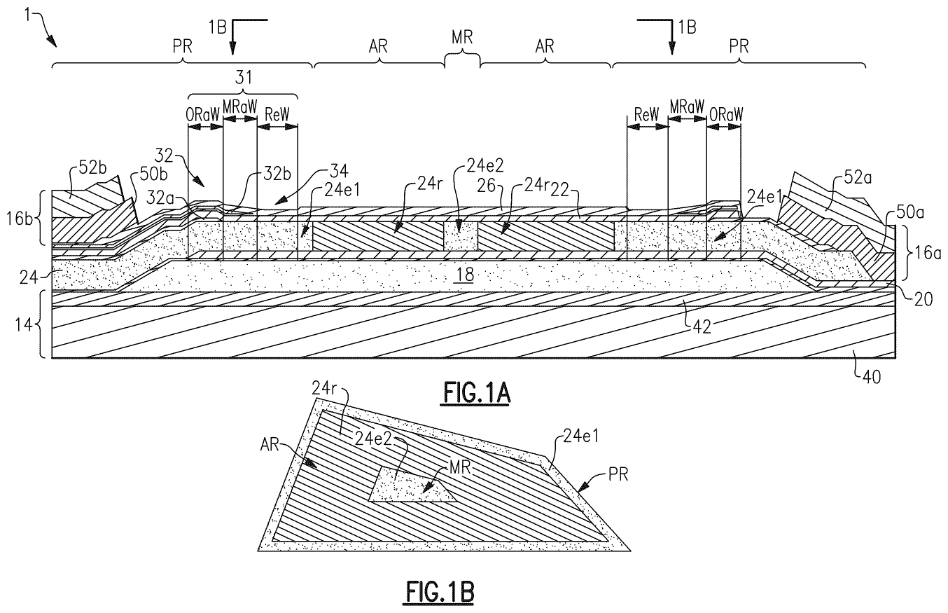

FIG. 1A is a schematic cross-sectional side view of a BAW device 1 according to an embodiment. FIG. 1B is a top plan view of a portion of the BAW device 1 of FIG. 1A. The BAW device 1 can include an acoustic reflector (e.g., a cavity 18), a first electrode 20, a second electrode 22, and a piezoelectric layer 24. The piezoelectric layer 24 includes a first engineered region 24e1 and a second engineered region 24e2. A region of the piezoelectric layer 24 that is not engineered can be referred to as a regular region 24r of the piezoelectric layer 24. A passivation layer 26 can be provided over the second electrode 22. With the second engineered region 24e2, the BAW device 1 can have a lower maximum temperature during operation than a similar BAW device without the second engineered region 24e2.

The piezoelectric layer 24 can be positioned between (e.g., vertically between) the first electrode 20 and the second electrode 22. The regular region 24r can be positioned laterally between the first engineered region 24e1 and the second engineered region 24e2. The second engineered region 24e2 can be laterally surrounded by the regular region 24r. The regular region 24r that surrounds the second engineered region 24e2 is over the cavity 24.

A region where the first electrode 20, the second electrode 22, and the piezoelectric layer 24 overlap over the acoustic reflector (e.g., the cavity 18) and generate an acoustic wave can define an acoustically active region AR of the BAW device 1. The first electrode 20, the second electrode 22, and the regular region 24r of the piezoelectric layer 24 overlap in the acoustically active region AR of the BAW device 1. The acoustically active region AR can include a main acoustically active region.

The BAW device 1 can include a middle region MR laterally surrounded by the active region AR. The piezoelectric layer 24 in the middle region MR is engineered and the second engineered region 24e2 of the piezoelectric layer 24 has an effective piezoelectric coefficient with a lower magnitude than an effective piezoelectric coefficient of the regular region 24r of the piezoelectric layer 24 in the acoustically active region AR.

The BAW device 1 can include a frame region outside of the main acoustically active region, and a peripheral region PR outside of the acoustically active region AR. The piezoelectric layer 24 in the peripheral region PR is engineered. The first engineered region 24e1 of the piezoelectric layer 24 in the peripheral region PR has an effective piezoelectric coefficient with a lower magnitude than an effective piezoelectric coefficient of the regular region 24r of the piezoelectric layer 24 in the acoustically active region AR. The frame region and the peripheral region PR can at least partially overlap. The frame region can include a raised frame region and a recessed frame region. In some embodiments, a recessed frame portion of the frame region can partially overlap the acoustically active region AR. In such embodiments, a region of the acoustically active region AR that does not overlap the frame region can be the main acoustically active region.

During operation of the BAW device 1, heat can be generated in the acoustically active region AR. The heat generated in the acoustically active region AR can be transferred through the piezoelectric layer 24 to other portions of the BAW device 1. For example, the heat can be transferred through the piezoelectric layer 24 to a support structure 14 where the cavity 18 is not positioned between the piezoelectric layer 24 and the support structure 14. The middle region MR that includes the second engineered region 24e2 can function as a cooling structure. The second engineered region 24e2 can reduce heat generation in the middle (e.g., at or near a center) of BAW device 1 by reducing or eliminating acoustic activity in the middle region MR. This can provide improved power handling and ruggedness for the BAW device 1. The location of the middle region MR where the second engineered region 24e2 is located can be determined based at least in part on locations of the acoustically active region AR that generate more heat absent the middle region MR. This may not be the exact center of the acoustically active region AR in some applications.

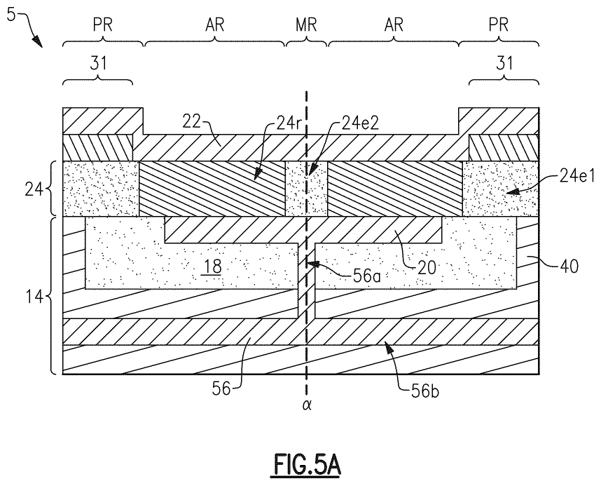

As shown in FIG. 1B, a shape of the second engineered region 24e2 in a plan view can conform to a shape of the BAW device 1, in some embodiments. The second engineered region 24e2 in a plan view can have any other suitable shape, such as a circular shape, a ring shape, a polygonal shape, an elliptical shape, a star shape, or an irregular shape, in some other embodiments. In certain embodiments, there can be a plurality of engineered portions or islands laterally surrounded by the regular region 24r of the piezoelectric layer 24 in the acoustically active region AR (see, for example, FIGS. 6B and 6C). According to some embodiments, an engineered region can form a ring surrounding a portion of a first regular region and a second regular region can surround the engineered region. In some such embodiments, another engineered region that vertically overlaps a frame structure can be positioned around the second region.

The BAW device 1 can include a frame structure 31 in the frame region. The frame structure 31 can include a raised frame structure 32 and/or a recessed frame structure 34. The recessed frame structure 34 can be positioned in the acoustically active region AR or be positioned in the peripheral region PR that is outside of the acoustically active region AR. In some embodiments, a mass loading structure (not shown) can be provided in the middle region MR. The mass loading structure can include a raised structure, such as a metal raised structure. The mass loading structure can further suppress a piezoelectric effect in the middle region MR. The second engineered region 24e2 can suppress an unwanted mode caused by the mass loading structure in the middle region MR.

The first and second engineered regions 24e1, 24e2 of the piezoelectric layer 24 can have a lower magnitude effective piezoelectric coefficient than the regular region 24r of the piezoelectric layer 24 in the acoustically active region AR. For example, the first and second engineered regions 24e1, 24e2 of the piezoelectric layer 24 can have an effective piezoelectric coefficient magnitude that is less than 50% of the effective piezoelectric coefficient magnitude of the regular region 24r of the piezoelectric layer 24 in the acoustically active region AR. As another example, the first and second engineered regions 24e1, 24e2 of the piezoelectric layer 24 can have an effective piezoelectric coefficient magnitude that is less than 20% of the effective piezoelectric coefficient magnitude of the regular region 24r of the piezoelectric layer 24 in the acoustically active region AR. As one more example, the first and second engineered regions 24e1, 24e2 of the piezoelectric layer 24 can have an effective piezoelectric coefficient magnitude that is less than 10% of the effective piezoelectric coefficient magnitude of the regular region 24r of the piezoelectric layer 24 in the acoustically active region AR. In some embodiments, the first and second engineered regions 24e1, 24e2 can be dielectric and the first and second engineered regions 24e1, 24e2 and portions of the first and second electrodes 20, 22 can define metal-insulator-metal capacitors. Even though the engineered regions 24e1 and 24e2 may have little or no piezoelectricity, the engineered regions 24e1 and 24e2 can be considered parts of the piezoelectric layer 24 of BAW devices of this disclosure.

The effective piezoelectric coefficient of the first engineered region 24e1 can be an aggregate piezoelectric coefficient for the entire first engineered region 24e1. The aggregate magnitude of the piezoelectric polarization vectors in the first engineered region 24e1 should be less than the magnitude in the regular region 24r. The effective piezoelectric coefficient of the second engineered region 24e2 can be an aggregate piezoelectric coefficient for the entire second engineered region 24e2. The aggregate magnitude of the piezoelectric polarization vectors in the second engineered region 24e2 should be less than the magnitude in the regular region 24r. The lower magnitude effective piezoelectric coefficient can be a result of the non-aligned nature of piezoelectric material crystal orientations within the first and second engineered regions 24e1, 24e2 causing a lower aggregate magnitude of the piezoelectric polarization vectors.

The effective piezoelectric coefficient can be an effective piezoelectric coupling coefficient (e₃₃), for example. The first engineered region 24e1 of the piezoelectric layer 24 can suppress the frame mode associated with the raised frame structure 32. The first engineered region 24e1 of the piezoelectric layer 24 can suppress the frame mode associated with the recessed frame structure 34. BAW devices with an engineered region of a piezoelectric layer vertically overlapping with a frame structure (e.g., a raised frame structure 32 and/or a recessed frame structure 34) disclosed herein can enable frame mode suppression, transverse mode suppression, and lateral mode suppression. At the same time, such BAW devices can achieve desirable quality factor (Q) values.

A boundary or border between the regular region 24r and the first engineered region 24e1 of the piezoelectric layer 24 can be the boundary or border between the active region AR and the peripheral region PR. The border between the regular region 24r and the first engineered region 24e1 can be adjusted to have more engineered region area +EPA or less engineered region area-EPA relative to the BAW device 1 shown in FIG. 1A. A boundary or border between the regular region 24r and the second engineered region 24e2 of the piezoelectric layer 24 can be the boundary or border between the active region AR and the middle region MR.

Referring to FIG. 1A, the first electrode 20 can be referred to as a lower electrode. The first electrode 20 can have a relatively high acoustic impedance. The first electrode 20 can include molybdenum (Mo), tungsten (W), ruthenium (Ru), chromium (Cr), iridium (Ir), platinum (Pt), or any suitable alloy and/or combination thereof. Similarly, the second electrode 22 can have a relatively high acoustic impedance. The second electrode 22 can include Mo, W, Ru, Cr, Ir, Pt, or any suitable alloy and/or combination thereof. The second electrode 22 can be formed of the same material as the first electrode 20 in certain applications. The second electrode 22 can be referred to as an upper electrode. The thickness of the first electrode 20 can be approximately the same as the thickness of the second electrode 22 in the acoustically active region AR of the BAW device 1.

The piezoelectric layer 24 can include a suitable material such as, but not limited to, aluminum nitride (AlN), zinc oxide (ZnO), or lead zirconium titanate (PZT). In certain applications, the piezoelectric layer 24 can be an AlN layer. The piezoelectric material can be doped or undoped. For example, an AlN-based piezoelectric layer can be doped with any suitable dopant, such as scandium (Sc), chromium (Cr), magnesium (Mg), sulfur(S), yttrium (Y), silicon (Si), germanium (Ge), oxygen (O), hafnium (Hf), zirconium (Zr), titanium (Ti), tantalum (Ta), boron (B), niobium (Nb), or the like. In certain applications, the piezoelectric layer 24 can be AlN based layer doped with Sc. Doping the piezoelectric layer 24 can adjust the resonant frequency. Doping the piezoelectric layer 24 can increase the electromechanical coupling coefficient (kt²) of the BAW device 1. Doping to increase the kt² can be advantageous at higher frequencies where kt² can be degraded. In certain applications, two or more piezoelectric layers of a BAW device can be implemented with any suitable principles and advantages disclosed herein.

The frame structure 31 can be configured to suppress the transverse mode. The raised frame structure 32 can reduce or impede propagation of transverse mode. As illustrated, the raised frame structure 32 is a multi-layer raised frame structure that includes a raised frame structure 32a and a raised frame structure 32b.

The raised frame structure 32b can include a material that has a relatively high mass density. For instance, the raised frame structure 32b can include Mo, W, Ru, the like, or any suitable alloy thereof. In some embodiments, the raised frame structure 32b and the second electrode 22 can be formed of a same material. The raised frame structure 32b can be a metal layer. Alternatively, the raised frame structure 32b can be a suitable non-metal material with a relatively high density. The density of the raised frame structure 32b can be similar to or heavier than the density of the first electrode 20 or the second electrode 22.

The raised frame structure 32a can include a low acoustic impedance material that has a lower acoustic impedance than the first electrode 20, the second electrode 22, and/or the piezoelectric layer 24. For example, the raised frame structure 32a can include a silicon dioxide (SiO₂) layer, a silicon nitride (SiN) layer, a silicon carbide (SiC) layer, or any other suitable low acoustic impedance layer. The raised frame structure 32a can be a dielectric layer. The raised frame structure 32a can be an oxide layer.

For example, the raised frame structure 32 shown in FIG. 1A includes an oxide raised frame structure 32a having a width ORaW, and a metal raised frame structure 32b having a width MRaW between the recessed frame structure 34 and the oxide raised frame structure 32a. The recessed frame structure 34 has a width ReW in the BAW device 1.

A frame structure can include, for example, a single layer raised frame structure, a multi-layer raised frame structure that includes two or more raised frame layers such as the illustrated raised frame structure 32, a recessed frame structure such as the illustrated recessed frame structure 34, or a combination of a raised frame structure and a recessed frame structure such as the illustrated frame structure 31. As an example, a frame structure can have a multi-layer raised frame structure that includes a relatively high density layer and a relatively low acoustic impedance layer. The low acoustic impedance layer can contribute to reducing an effective electromechanical coupling coefficient (kt²) relative to a single high-density raised frame structure, which can reduce excitation strength of a raised frame spurious mode. As another example, a floating raised frame structure can be implemented. In the BAW device 1, the frame structure 31 is illustrated as being asymmetric about the acoustically active region AR. However, in some embodiments, the frame structure 31 can be symmetric about the acoustically active region AR.

The support structure 14 can include a support substrate 40 and an intermediate layer 42 between the support substrate and the first electrode 20. The support substrate 40 can be a semiconductor substrate. The support substrate 40 can be a silicon substrate. The support substrate 40 can be any other suitable support substrate, such as a substrate of quartz, silicon carbide, sapphire, glass, gallium arsenide, or any suitable ceramic (e.g., spinel, alumina, etc.).

The intermediate layer 42 can include, for example, one or more of a seed layer, a trap rich layer, a passivation layer, or one or more other suitable functional layers. In some embodiments, the intermediate layer 42 can be completely or partially omitted. In some such embodiments, a portion of the first electrode 20 can directly contact the support substrate 40. The intermediate layer 42 can be relatively thin. For example, the intermediate layer 42 can be significantly thinner than the support substrate 40. Heat generated by the BAW device 1 can dissipate through the first electrode 20 to the support substrate 40 at a location where there is no cavity 18 between the first electrode 20 and the support substrate 40.

As shown in FIG. 1A, a first interconnect structure 16a can include one or more conductive layers such as a first conductive layer 50a and a second conductive layer 52a. Similarly, a second interconnect structure 16b can include one or more conductive layers such as a first conductive layer 50b and a second conductive layer 52b. The first conductive layers 50a, 50b and the second conductive layers 52a, 52b can each include a material suitable for interconnecting the BAW device 1 and one or more other component (e.g., another resonator) in a filter, an external component, or a ground connection. The first conductive layers 50a, 50b and/or the second conductive layers 52a, 52b can be highly conductive. For example, the first conductive layers 50a, 50b and/or the second conductive layers 52a, 52b can be more electrically conductive than the first electrode 20 and/or the second electrode 22. In some embodiments, the first conductive layers 50a, 50b and/or the second conductive layers 52a, 52b can include one or more of gold (Au), titanium (Ti), copper (Cu), aluminum (Al), or tungsten (W).

The cavity 18 (e.g., an air cavity) can be formed between the support substrate 40 and the first electrode 20. Heat generated by the piezoelectric layer 24 can flow laterally over the cavity 18 to a heat dissipation path where the BAW device 18 is free from the cavity 18 between the piezoelectric layer 23 and the support structure 14. The cavity 18 is an example of an acoustic reflector. The BAW device 1 can be a film bulk acoustic wave resonator (FBAR). In some other embodiments, there can be a solid acoustic mirror in place of the cavity 18 and such a BAW device can be a BAW solidly mounted resonator (SMR).

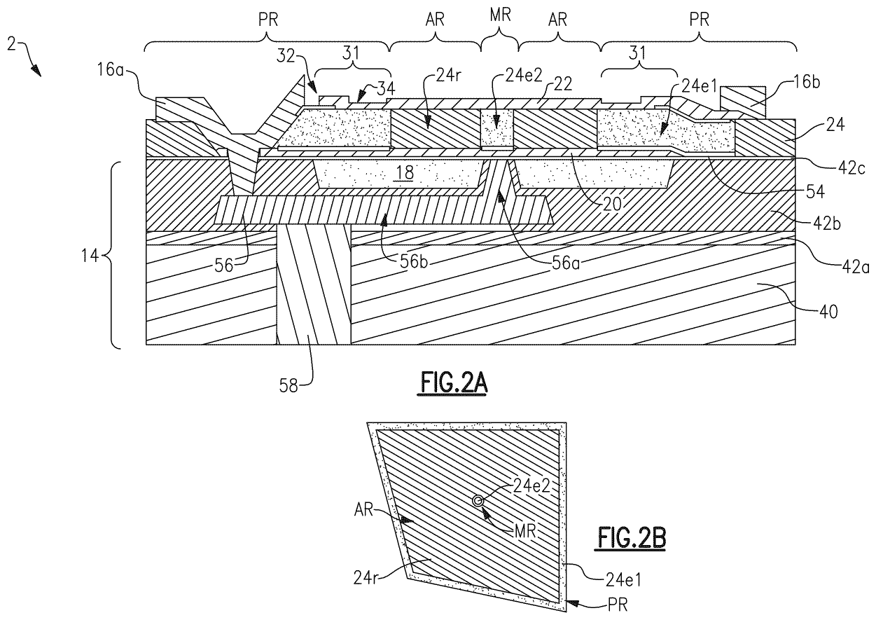

An additional heat dissipation path can be included in a BAW device relative to the BAW device 1 to further improve heat dissipation in the BAW device. For example, a thermally conductive structure, such as a thermally conductive pillar, can be provided between the second engineered region 24e2 and the support structure 14 to provide a heat path therebetween. Examples of such embodiments are shown in FIGS. 2A-5.

FIG. 2A is a schematic cross-sectional side view of a BAW device 2 according to an embodiment. FIG. 2B is a schematic top plan view of the BAW device 2. Unless otherwise noted, the components of the BAW device 2 shown in FIGS. 2A and 2B may be structurally and/or functionally the same as or generally similar to like components of other BAW devices disclosed herein.

The BAW device 2 can include an acoustic reflector (e.g., a cavity 18), a first electrode 20, a second electrode 22, and a piezoelectric layer 24. The piezoelectric layer 24 includes a first engineered region 24e1 and a second engineered region 24e2. A seed layer 54 can be provided below the first and second engineered regions 24e1, 24e2 of the piezoelectric layer 24. The seed layer 54 is between the first and second engineered regions 24e1 and 24e2, respectively, and the first electrode 20. A region of the piezoelectric layer 24 that is not engineered can be referred to as a regular region 24r of the piezoelectric layer 24. The piezoelectric layer 24 can be positioned between (e.g., vertically between) the first electrode 20 and the second electrode 22. The regular region 24r can be positioned laterally between the first engineered region 24e1 and the second engineered region 24e2. The second engineered region 24e2 can be positioned between portions of the regular region 24r. For example, the second engineered region 24e2 can be laterally surrounded by the regular region 24r. The regular region 24r laterally surrounds the second engineered region 24e2 over the cavity 18 in the BAW device 2.

The BAW device 2 can include a support structure 14 including a support substrate 40 and an intermediate layer structure 42. The intermediate layer structure 42 can include a trap-rich layer 42a, a dielectric layer 42b and a passivation layer 42c. The support substrate 14 can also include conductive structures 56, 58. The conductive structures 56, 58 can be thermally conductive and/or electrically conductive. The conductive structures 56, 58 can be configured to dissipate heat generated by the BAW device 2. In some embodiments, the conductive structure 56 can provide a thermal and electrical pathway between the second engineered region 24e2 and the first interconnect structure 16a, and also provide a thermal pathway between the second engineered region 24e2 and the conductive structure 58. The conductive structures 56, 58 can also be referred to as heat paths or heat dissipation paths.

The conductive structure 56 can include a pillar 56a that extends in the cavity 18 and a trace 56b that extends laterally through a portion of the dielectric layer 42b. The second engineered region 24e2 can make the piezoelectric layer 24 mostly or completely inactive over the pillar 56a. Accordingly, the pillar 56a can be provided in a central region of the BAW device 2 without creating a vibration mode having a different frequency than the acoustically active region AR due to different mass loading from the pillar 56a. The pillar 56a can be in physical contact with the first electrode 20. In some embodiments, the conductive structure 56 can be at least partially embedded in the dielectric layer 42b. For example, as illustrated in FIG. 2A, the trace 56b is fully embedded in the dielectric layer 42b. In such embodiments, a thickness of the dielectric layer 42b can be sufficiently thick to accommodate the conductive structure 56. The trace 56b can be referred to as a buried conductor. The conductive structure 58 includes a through substrate via. The conductive structure 58 can extend at least partially through the dielectric layer 42b, the trap-rich layer 42a, and the support substrate 40. The heat generated in the active region AR of the BAW device 2 can flow through the second engineered region 24e2, the first electrode 20, and the conductive structures 56, 58. The conductive structures 56, 58 can improve thermal performance of the BAW device 2 relative to the BAW device 1. In FIG. 2A, the first electrode 20 is connected directly to the first interconnect structure 16a. The trace 56b can include a relatively high thermal dielectric material, such as aluminum nitride (AlN) or beryllium oxide (BeO), in certain applications. The conductive structures 56, 58 may be electrically conductive structures that are formed of electrically conductive and/or metallic material. In some embodiments, the structures 56 can include molybdenum, copper, chromium, or a metal alloy. The conductive structures 56, 58 may include the same material as the first electrode 20 in certain applications. The structures 56, 58 may include different materials in some applications.

FIG. 2B can illustrate the scale of the middle region MR and the pillar 56a in certain embodiments more accurately than FIG. 2A. The pillar 56a can be in a relatively small area of the BAW device 2. The pillar 56a can have a width or diameter in a range between 0.5 micrometers and 30 micrometers. For example, the width or diameter of the pillar 56a can be in a range between 0.5 microns and 10 microns, 3 microns and 10 microns, or 5 microns and 10 microns. A width or diameter of the second engineered region 24e2 can be the same as, greater than, or less than the width or diameter of the pillar 56a. For example, the width or diameter of the second engineered region 24e2 can be within 3%, 5%, or 7% of the width or diameter of the pillar 56a.

In some embodiments, the seed layer 54 can be provided by way of deposition. The seed layer 54 may include, for example, atomic layer deposited aluminum nitride layer. In the BAW device 2, the seed layer 54 can cause the piezoelectric layer 24 to be engineered in the first and second engineered regions 24e1, 24e2. The seed layer 54 can be a material that has poor crystallinity or is crystalline with a poor lattice match to the piezoelectric film applied over the seed layer 54. The seed layer 54 can include, but is not limited to, an oxide, a nitride, a carbide, a carbon structure (e.g., graphene or diamond), a boride, or any suitable combination thereof. In certain applications, the seed layer 54 can include one or more of aluminum oxide, silicon, silicon carbide, doped aluminum nitride, undoped aluminum nitride, aluminum, fused silica, boron nitride, diamond, silicon oxycarbide glass, silicon oxynitride glass, boron carbide, graphene, beryllium oxide, gallium nitride, indium nitride, silicon nitride, scandium nitride, or the like. In some embodiments, the seed layer 54 can have a thickness that is in a single digit nanometer range. In some embodiments, the seed layer 54 can have a thickness that is in a range from 10 nanometers to 100 nanometers.

The top plan view of the BAW device 2 shown in FIG. 2B shows that the second engineered region 24e2 can be laterally surrounded by the regular region 24r. The top plan view shape of a BAW device, such as the BAW device 2, can be any other suitable shape.

FIG. 2C is another example schematic top plan view of the BAW device 2. Unless otherwise noted, the components of the BAW device 2 shown in FIG. 2C may be structurally and/or functionally the same as or generally similar to like components of other BAW devices disclosed herein. The principles and advantages disclosed herein regarding the second engineered region 24e2 and the conductive structures 56, 58 can be implemented in BAW devices with a variety of shapes in top plan view.

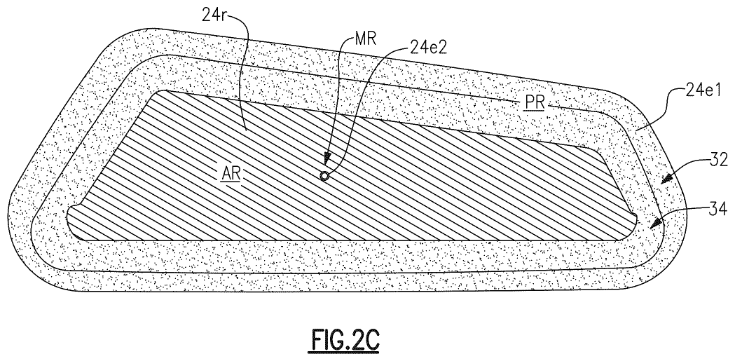

In some embodiments, the frame structure 31 can be structurally and/or functionally symmetric (e.g., reflection symmetry, rotational symmetry, translational symmetry, glide symmetry, point symmetry, or bilateral symmetry) in a cross-sectional view. FIGS. 3A-5 show examples of such symmetric frame structures.

FIG. 3A is a schematic cross-sectional side view of a BAW device 3 according to an embodiment. FIG. 3B is a schematic top plan view of the BAW device 3. Unless otherwise noted, the components of the BAW device 3 shown in FIGS. 3A and 3B may be structurally and/or functionally the same as or generally similar to like components of other BAW devices disclosed herein. The BAW device 3 of FIGS. 3A and 3B can be generally similar to the BAW device 2 of FIGS. 2A-2C. Unlike the BAW device 2, the first interconnect structure 16a for the first electrode 20 is not provided in the peripheral region PR of the BAW device 3. In the cross-sectional view, the BAW device 3 can be symmetric about the middle region MR. The conductive structures 56, 58 can function as a thermal path to dissipate heat from the second engineered region 24e2. In certain embodiments, the conductive structure 56, 58 can function as an electrical path to provide an electrical connection for the first electrode 20 (e.g., function like the first interconnect structure 16a). In some applications, the conductive structure 56 can provide electrical path to another BAW device or circuit element of a filter that is over the same support substrate 40 as the BAW device 3. FIG. 3B illustrates that the conductive pillar 56a and the second engineered region 24e2 of the piezoelectric layer 24 can be in a relatively small area of the BAW device 3. FIG. 3B can more accurately reflect the scale of the second engineered region 24e2 of the piezoelectric layer 24 of the BAW device 3 than FIG. 3A.

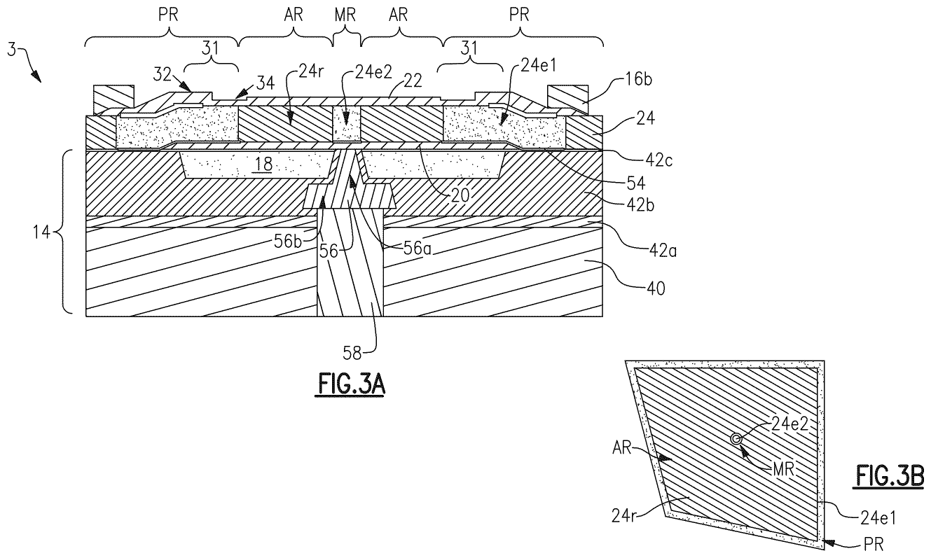

FIG. 4 is a schematic cross-sectional side view of a BAW structure 4 including BAW devices 4a, 4b according to an embodiment. Unless otherwise noted, the components of the BAW structure 4 shown in FIG. 4 may be structurally and/or functionally the same as or generally similar to like components of other BAW devices disclosed herein.

The BAW structure 4 can include two BAW devices 4a, 4b. The BAW devices 4a, 4b of the BAW structure 4 can each include an acoustic reflector (e.g., a cavity 18, 18′), a first electrode 20, 20′, a second electrode 22, 22′, and a piezoelectric layer 24. The piezoelectric layer 24 includes, in each BAW device 4a, 4b, a first engineered region 24e1, 24e1′, and a second engineered region 24e2, 24e2′. A seed layer 54, 54′ can be provided below the first and second engineered regions 24e1, 24e1′, 24e2, 24e2′. A region of the piezoelectric layer 24 that is not engineered can be referred to as a regular region 24r, 24r′ of the piezoelectric layer 24. In some embodiments, the structures of the BAW device 4a, 4b can be generally the same such that the BAW structure 4 can be symmetric about an axis α.

The BAW devices 4a, 4b can share the same conductive structure 58. The heat generated by the BAW devices 4a, 4b can flow through the conductive structure 56 to the conducive structure 58. In some other embodiments, the conductive structure 58 may be shared by three or more BAW devices. When there are a plurality of engineered regions for heat dissipation in a single BAW device, there may be a corresponding number of pillars 56a of the conductive structure 56 that connect the plurality of engineered regions to the conductive structure 58.

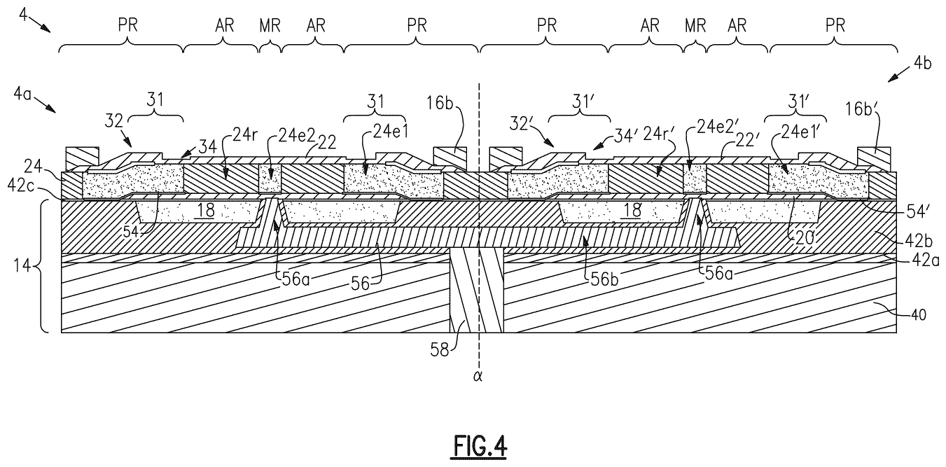

FIG. 5A is a schematic cross-sectional side view of a BAW device 5 according to an embodiment. Unless otherwise noted, the components of the BAW device 5 shown in FIG. 5A may be structurally and/or functionally the same as or generally similar to like components of other BAW devices disclosed herein. As with other BAW devices disclosed herein, the BAW device 5 can include a support substrate 40, a pair of electrodes (e.g., a first electrode 20 and a second electrode 22), a piezoelectric layer 24 having a first engineered region 24e1, a second engineered region 24e2, and a regular region 24r.

In the BAW device 5, the frame structure 31, the first and second engineered regions 24e1, 24e2, and the conductive structure 56 can be symmetric about an axis α extending through the piezoelectric layer 24. The BAW device 5 can be symmetrical about the axis α. The electrical connection to and/or from the first electrode 20 can be made through the conductive structure 56. The conductive structure 56 can include a pillar 56a that extends from the first electrode 20 to the support substrate 40 and a trace 56b that laterally extends at least partially through the substrate 40. The trace 56b can be buried in the substrate 40 and at least partially extend laterally. The trace 56b can be referred to as a buried conductor.

FIG. 5B is an example of a BAW solidly mounted resonator (SMR) 3a according to an embodiment. FIG. 5B shows that the principles and advantages disclosed herein regarding the second engineered region 24e2 and the conductive structures 56, 58 can be implemented in a BAW SMR. Unless otherwise noted, the components of the BAW SMR 3a shown in FIG. 5B may be structurally and/or functionally the same as or generally similar to like components of other BAW devices disclosed herein. In place of the cavity 18 shown in one or more other figures, the BAW SMR 3a includes a solid acoustic mirror 78 between the support substrate 40 and the first electrode 20. The illustrated acoustic mirror 78 includes acoustic Bragg reflectors. The illustrated acoustic Bragg reflectors can include alternating low impedance layers 78a and high impedance layers 78b. As an example, the Bragg reflectors can include alternating silicon dioxide layers as low impedance layers 78a and tungsten layers as high impedance layers 78b. Any other suitable features of a BAW SMR can alternatively or additionally be implemented. Any other suitable features of BAW devices disclosed herein can be implemented in a BAW SMR. The conductive structure 56 can extend at least partially through the solid acoustic mirror 78 and the conductive structure 58 can extend at least partially through the support substrate 40.

The location of the middle region MR where the second engineered region 24e2 is located can be determined based at least in part on locations of the acoustically active region AR that generate more heat with and/or without the middle region MR. For example, thermal simulations can be conducted without the middle region MR and the position of the middle region MR can be determined from such thermal simulations. Alternatively or additionally, thermal simulations can be conducted for various locations of the middle region MR and the position of the middle region MR can be determined from such thermal simulations. The location of the acoustically active region AR that generates more heat without the middle region MR may be offset from the center of the acoustically active region AR. In some embodiments, there can be two or more middle regions MR in which the piezoelectric layer 24 is engineered. A conductive structure 56 can be provided for each engineered region in the middle region MR.

FIGS. 6A, 6B, and 6C are schematic top plan views of BAW devices 6a, 6b, 6c. Unless otherwise noted, the components of the BAW devices 6a, 6b, 6c shown in FIGS. 6A-6C may be structurally and/or functionally the same as or generally similar to like components of other BAW devices disclosed herein. Any suitable principles and advantages disclosed herein regarding the second engineered region 24e2 and the conductive structures 56, 58 can be implemented with the BAW devices 6a, 6b, 6c of FIGS. 6A-6C. As shown in FIG. 6A, the middle region MR where the second engineered region 24e2 is located can be offset from the center of the BAW device 6a in the plan view. As shown in FIGS. 6B and 6C, there can be a plurality of middle regions MR in which the second engineered region 24e2 is provided. In the BAW devices 6b and 6c, a plurality of thermally conductive structures that include pillars can be implemented. Such pillars can be connected by a trace to connect the pillars to a common conductive through substrate via in certain applications. In some applications, pillars of thermally conductive structures of the BAW devices 6b and/or 6c can be connected to respective through substrate vias.

BAW devices disclosed herein can be implemented in a variety of applications. Applications of these BAW devices include, but are not limited to, a BAW resonator for filter that filters an electrical signal, a BAW oscillator such as a BAW oscillator for a clock generator, a BAW sensor (e.g., a gas sensor, a particle sensor, a mass sensor, a pressure or touch sensor, etc.), a BAW delay line such as BAW delay line for radar and/or instrumentation applications, an actuator, a microphone, and a speaker. Filters that include BAW resonators can be implemented in a variety of applications including, but not limited to, mobile phones, base stations, repeaters, relays, wireless communication infrastructure, access points, customer premises equipment (CPE), and distributed antenna systems. BAW oscillators can replace crystal oscillators in a variety of applications, such as but not limited to electronic timing products.

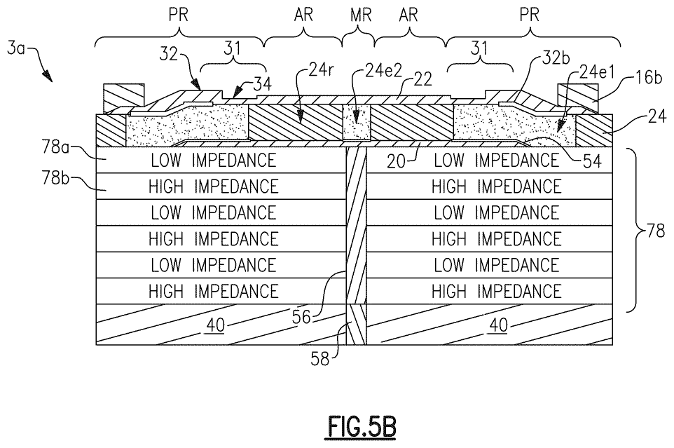

BAW devices disclosed herein can be implemented as BAW resonators in a variety of filters. Such filters can be arranged to filter a radio frequency signal. BAW devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 7A.

FIG. 7A is a schematic diagram of a ladder filter 200 that includes an acoustic wave resonator according to an embodiment. The ladder filter 200 is an example topology that can implement a band pass filter formed of acoustic wave resonators. In a band pass filter with a ladder filter topology, the shunt resonators can have lower resonant frequencies than the series resonators. The ladder filter 200 can be arranged to filter a radio frequency signal. As illustrated, the ladder filter 200 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, the first input/output port I/O₁ can be a receive port and the second input/output port I/O₂ can be an antenna port. One or more of the acoustic wave resonators of the ladder filter 200 can include a BAW resonator in accordance with any suitable principles and advantages disclosed herein. All acoustic resonators of the ladder filter 200 can include a BAW resonator in accordance with any suitable principles and advantages disclosed herein.

A filter that includes a BAW resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band. A filter that includes a BAW resonator in accordance with any suitable principles and advantages disclosed herein can be arranged to filter a radio frequency signal in any other suitable operating band, such as a WiFi operating band, a Global Positioning System (GPS) operating band, a Bluetooth operating band, a ZigBee operating band, a WiMax operating band, etc.

The BAW devices disclosed herein can be advantageous for implementing BAW resonators with relatively high Qp, relatively low spur intensity, and desirable heat dissipation. Such BAW resonators can have desirable power handling and ruggedness characteristics. BAW resonators disclosed herein can have significantly better performance than a variety of other BAW resonators. This can be advantageous in meeting demanding specifications for acoustic wave filters, such as performance specifications for certain 5G applications.

FIG. 7B is schematic diagram of an acoustic wave filter 260. The acoustic wave filter 260 can include the acoustic wave resonators of the ladder filter 200. The acoustic wave filter 260 is a band pass filter. The acoustic wave filter 260 is arranged to filter a radio frequency signal. The acoustic wave filter 260 includes one or more acoustic wave devices coupled between a first input/output port RF_IN and a second input/output port RF_OUT. The acoustic wave filter 260 includes a BAW resonator according to an embodiment.

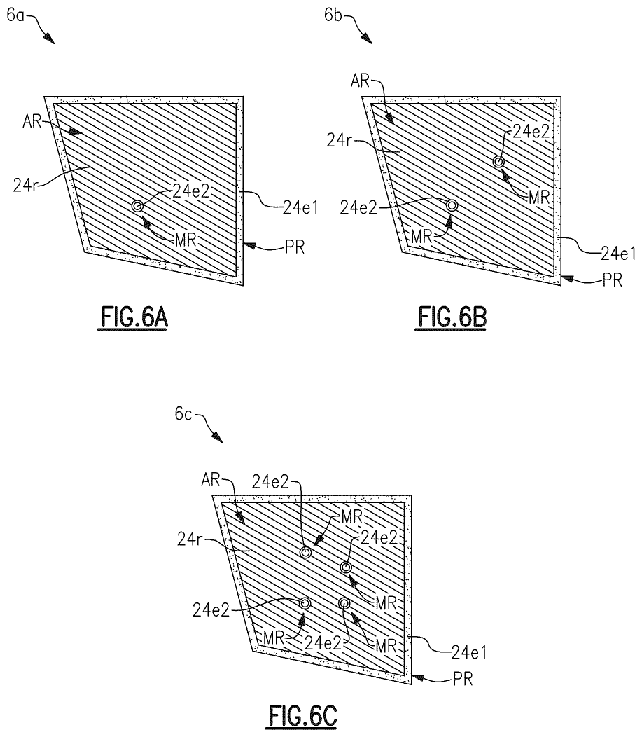

The BAW devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 8A to 8D. Any suitable principles and advantages of these multiplexers can be implemented together with each other.

FIG. 8A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a BAW resonator in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a BAW resonator in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 8B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a BAW resonator in accordance with any suitable principles and advantages disclosed herein. The other filter(s) of the multiplexer 264 can include one or more acoustic wave filters, one or more acoustic wave filters that include a BAW resonator in accordance with any suitable principles and advantages disclosed herein, one or more LC filters, one or more hybrid acoustic wave LC filters, the like, or any suitable combination thereof.

FIG. 8C is a schematic diagram of a multiplexer 266 that includes an acoustic wave filter according to an embodiment. The multiplexer 266 is like the multiplexer 264 of FIG. 8B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 8D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

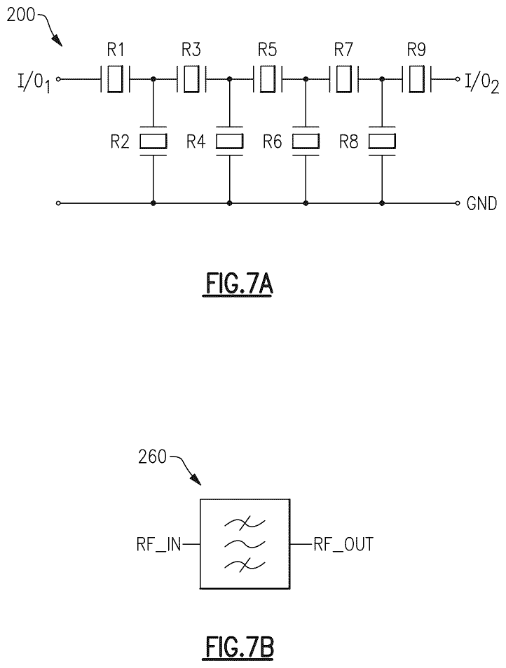

Acoustic wave devices disclosed herein can be implemented in a variety of packaged modules. Some example packaged modules will now be disclosed in which any suitable principles and advantages of the BAW devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 9, 10, and 11 are schematic block diagrams of illustrative packaged modules according to certain embodiments. Any suitable combination of features of these packaged modules can be implemented with each other.

FIG. 9 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW devices in certain applications.

The acoustic wave component 272 shown in FIG. 9 includes one or more acoustic wave devices 274 and terminals 275A and 275B. The one or more acoustic wave devices 274 include one or more BAW devices implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 9. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

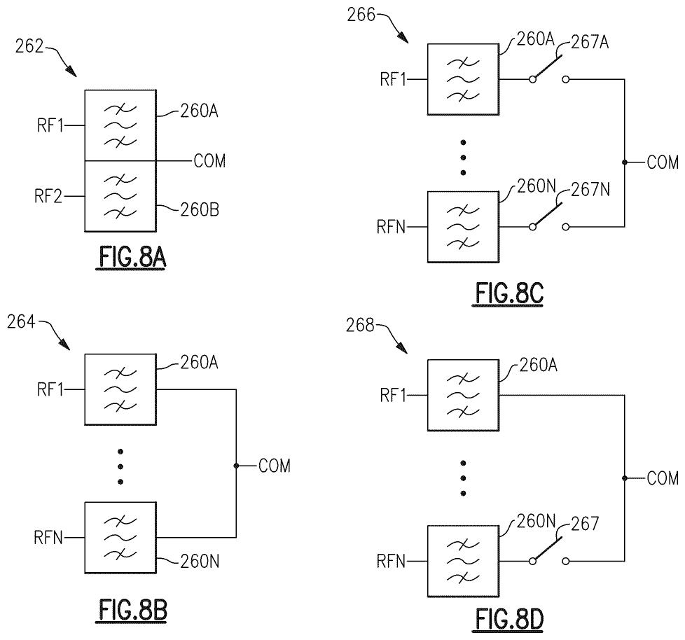

FIG. 10 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

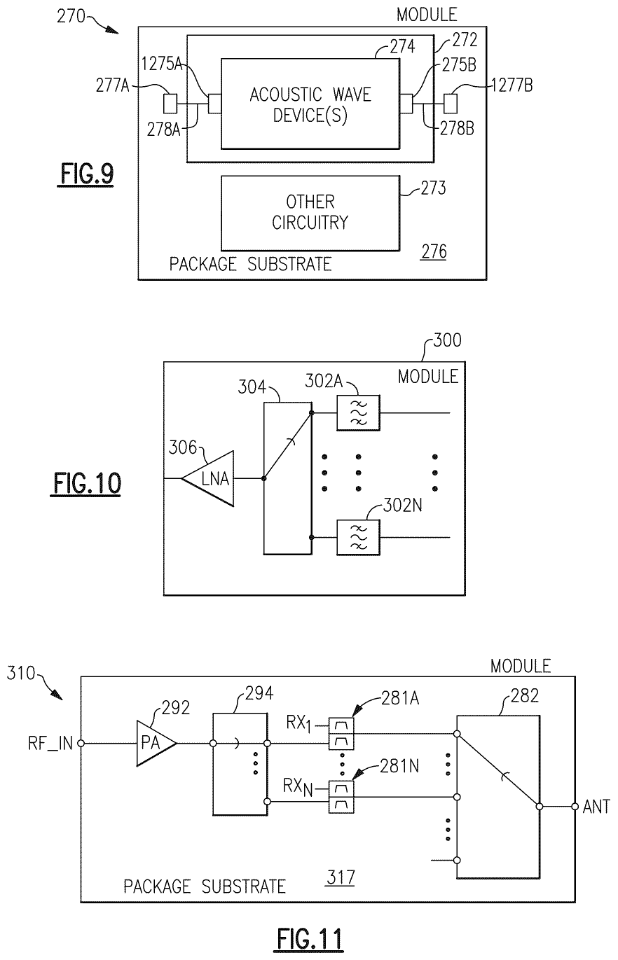

FIG. 11 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 11 and/or additional elements. The radio frequency module 310 may include any one of the acoustic wave filters that include at least one bulk acoustic wave resonator in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW device in accordance with any suitable principles and advantages disclosed herein. Similarly, one or more of the receive filters can include a BAW device in accordance with any suitable principles and advantages disclosed herein. Although FIG. 11 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

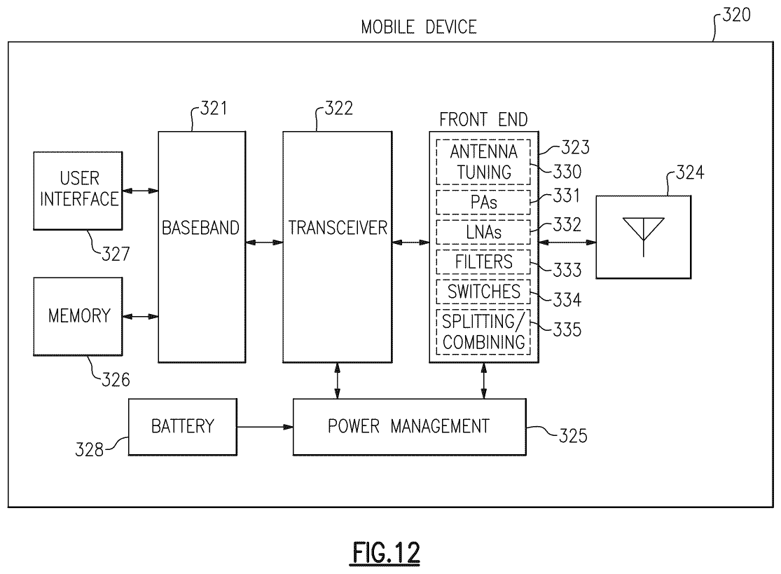

The BAW devices disclosed herein can be implemented in wireless communication devices. FIG. 12 is a schematic block diagram of a wireless communication device 320 that includes a BAW device according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 12 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAs) 331, low noise amplifiers (LNAs) 332, filters 333, switches 334, and signal splitting/combining circuitry 335. However, other implementations are possible. The filters 333 can include one or more acoustic wave filters that include any suitable number of BAW devices in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 12, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 12, the power management system 325 receives a battery voltage from the battery 328. The battery 328 can be any suitable battery for use in the wireless communication device 320, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz, in FR1, in a frequency range from about 2 GHz to 10 GHz, in a frequency range from about 2 GHz to 15 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to. ” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device comprising:
an acoustic reflector;
a first electrode;
a second electrode; and
a piezoelectric layer positioned vertically between the first electrode and the second electrode, the piezoelectric layer including a first region having a first effective piezoelectric coefficient and a second region having a second effective piezoelectric coefficient, the first effective piezoelectric coefficient having a greater magnitude than the second effective piezoelectric coefficient, the first region vertically overlapping with the acoustic reflector, and the first region laterally surrounding the second region.

2. The bulk acoustic wave device of claim 1 wherein the second region is located at a center of the first region.

3. The bulk acoustic wave device of claim 1 wherein the piezoelectric layer includes one or more additional regions each having a respective effective piezoelectric coefficient with a lower magnitude than the first effective piezoelectric coefficient, and the first region laterally surrounding each of the one or more additional regions.

4. The bulk acoustic wave device of claim 1 wherein portions of the first and second electrodes and the second region of the piezoelectric layer form a metal-insulator-metal capacitor.

5. The bulk acoustic wave device of claim 1 wherein the piezoelectric layer further includes a third region laterally surrounding the first region, the first effective piezoelectric coefficient having a greater magnitude than a third effective piezoelectric coefficient of the third region.

6. The bulk acoustic wave device of claim 5 further comprising a frame structure vertically overlapping the third region.

7. The bulk acoustic wave device of claim 6 further comprising a thermally conductive structure in thermal communication with the second region of the piezoelectric layer, the thermally conductive structure configured to provide a heat dissipation path away from the piezoelectric layer.

8. The bulk acoustic wave device of claim 1 further comprising a thermally conductive structure in thermal communication with the second region of the piezoelectric layer, the thermally conductive structure extending through the acoustic reflector.

9. The bulk acoustic wave device of claim 1 further comprising a thermally conductive pillar at least partly vertically overlapping with the second region of the piezoelectric layer.

10. The bulk acoustic wave device of claim 9 wherein the thermally conductive pillar is in physical contact with the first electrode.

11. The bulk acoustic wave device of claim 9 further comprising a conductor embedded in a dielectric layer connected to the thermally conductive pillar.

12. The bulk acoustic wave device of claim 11 further comprising a support substrate and a conductive through substrate via extending through the support substrate, the piezoelectric layer positioned over the support substrate, and the conductive through substrate via connected to the conductor embedded in the dielectric layer.

13. The bulk acoustic wave device of claim 1 wherein the acoustic reflector is an air cavity.

14. A bulk acoustic wave device having a middle region, a peripheral region, and an acoustically active region between the middle region and the peripheral region, the bulk acoustic wave device comprising:
a first electrode;
a second electrode; and
a piezoelectric layer positioned between the first electrode and the second electrode, the piezoelectric layer having an effective piezoelectric coefficient in the acoustically active region with a higher magnitude than in the middle region and the peripheral region.

15. The bulk acoustic wave device of claim 14 wherein the middle region is located at a center of the acoustically active region.

16. The bulk acoustic wave device of claim 14 further comprising a raised frame structure in the peripheral region.

17. The bulk acoustic wave device of claim 14 further comprising a thermally conductive pillar in the middle region.

18. The bulk acoustic wave device of claim 17 further comprising a conductor embedded in a dielectric layer connected to the thermally conductive pillar.

19. The bulk acoustic wave device of claim 18 further comprising a support substrate and a conductive through substrate via extending through the support substrate, the piezoelectric layer positioned over the support substrate, and the conductive through substrate via connected to the conductor embedded in the dielectric layer.

20. An acoustic wave filter for filtering a radio frequency signal, the acoustic wave filter comprising:
a bulk acoustic wave device including an acoustic reflector, a first electrode, a second electrode, a piezoelectric layer positioned vertically between the first electrode and the second electrode, the piezoelectric layer including a first region having a first effective piezoelectric coefficient and a second region having a second effective piezoelectric coefficient, the first effective piezoelectric coefficient having a greater magnitude than the second effective piezoelectric coefficient, the first region vertically overlapping with the acoustic reflector, and the first region laterally surrounding the second region; and
a plurality of additional acoustic wave resonators, the bulk acoustic wave device and the plurality of additional acoustic wave resonators configured to filter the radio frequency signal.
